(19) United States
(12) Patent Application Publication
(10) Pub. No.: US 2013/0269771 A1
(43) Pub. Date: Oct. 17, 2013

(54) SOLAR CELL

(71) Applicant: LG ELECTRONICS INC., Seoul (KR)

(72) Inventors: Hyeunseok CHEUN, Seoul (KR); Heonmin LEE, Seoul (KR); Wonki YOON, Seoul (KR); Gunho KIM, Seoul (KR)

(73) Assignee: LG ELECTRONICS INC., Seoul (KR)

(21) Appl. No.: 13/863,991

(22) Filed: Apr. 16, 2013

(30) Foreign Application Priority Data
Apr. 17, 2012 (KR) 10-2012-039934

(51) Int. Cl. H01L 31/0224

(52) U.S. Cl. CPC H01L 31/022483
USPC 136/256

(57) ABSTRACT

A solar cell includes a substrate of a first conductive type, an emitter region which is positioned at a first surface of the substrate and has a second conductive type different from the first conductive type, a first surface field region which is positioned at the first surface of the substrate and separated from the emitter region, a first auxiliary electrode positioned directly on the emitter region, a second auxiliary electrode positioned directly on the first surface field region, a first main electrode positioned directly on the first auxiliary electrode, and a second main electrode positioned directly on the second auxiliary electrode. Each of the first and second auxiliary electrodes is a transparent conductive layer formed by doping a transparent conductive oxide layer with a conductive material.

This application claims priority to and the benefit of Korean Patent Application No. 10-2012-0039934 filed in the Korean Intellectual Property Office on Apr. 17, 2012, the entire contents of which are incorporated herein by reference.

### BACKGROUND OF THE INVENTION

1. Field of the Invention

Embodiments of the invention relate to a solar cell.

2. Description of the Related Art

Recently, as existing energy sources such as petroleum and coal are expected to be depleted, interests in alternative energy sources for replacing the existing energy sources are increasing. Among the alternative energy sources, solar cells for generating electric energy from solar energy have been particularly spotlighted.

A solar cell generally includes semiconductor parts, which respectively have different conductive types, for example, a p-type and an n-type and thus form a p-n junction, and electrodes respectively connected to the semiconductor parts of the different conductive types.

When light is incident on the solar cell, electrons and holes are produced in the semiconductor parts. The electrons move to the n-type semiconductor part, and the holes move to the p-type semiconductor part under the influence of the p-n junction of the semiconductor parts. Then, the electrons and the holes are collected by the different electrodes respectively connected to the n-type semiconductor part and the p-type semiconductor part. The electrodes are connected to each other using electric wires to thereby obtain electric power.

### SUMMARY OF THE INVENTION

In one aspect, there is a solar cell including a substrate of a first conductive type formed of a crystalline semiconductor, an emitter region positioned at a first surface of the substrate, the emitter region having a second conductive type different from the first conductive type, a first surface field region which is positioned at the first surface of the substrate and separated from the emitter region and has the first conductive type, a first auxiliary electrode positioned directly on the emitter region, a second auxiliary electrode positioned directly on the first surface field region, a first main electrode positioned directly on the first auxiliary electrode, and a second main electrode positioned directly on the second auxiliary electrode, wherein each of the first and second auxiliary electrodes is a transparent conductive layer formed by doping a transparent conductive oxide layer having conductivity of about 1,000 S/cm to 3,000 S/cm with a conductive material.

Each of the first and second auxiliary electrodes may include a plurality of layers each including a first oxide layer and a second oxide layer thicker than the first oxide layer.

The first oxide layer may be an aluminum oxide layer, and the second oxide layer may be a zinc oxide layer.

A thickness ratio of the first oxide layer to the second oxide layer may be about 1:8 to 1:80.

Each of the first and second auxiliary electrodes may have a thickness of about 100 nm to 1,000 nm.

The solar cell may further include a first buffer which is positioned between the first surface of the substrate and the emitter region and between the first surface of the substrate and the first surface field region and is formed of a non-crystalline semiconductor.

The solar cell may further include a second buffer which is positioned on a second surface opposite the first surface of the substrate and is formed of a non-crystalline semiconductor.

The solar cell may further include a second surface field region which is positioned at the second surface of the substrate and has the first conductive type.

The solar cell may further include an anti-reflection layer which is positioned on the second surface of the substrate and decreases reflection of light.

The substrate may be formed of a crystalline semiconductor, and the emitter region and the first surface field region may be formed of a non-crystalline semiconductor.

The substrate may be formed of a crystalline semiconductor, and the emitter region and the first surface field region may be formed of a crystalline semiconductor.

Light may not be incident on the first surface of the substrate.

Each of the first and second auxiliary electrodes may have a nanolaminate structure including a plurality of layers, whereby each of the plurality of layers includes a plurality of sub-layers, each of which is formed each time an atomic layer deposition cycle is performed once.

One of the plurality of sub-layers is an aluminum oxide layer, and the remainder of the plurality of sub-layers may be zinc oxide layers.

The number of the zinc oxide layers may be 10 to 40.

A thickness of the aluminum oxide layer may be about 1 Å to 1.5 Å, and a thickness of each zinc oxide layer may be about 1.3 Å to 2.4 Å.

The aluminum oxide layer may be positioned directly on the emitter region or the first surface field region, and the zinc oxide layers may be positioned on the aluminum oxide layer.

According to the above-described characteristics of the solar cell, the first and second auxiliary electrodes, each of which is the transparent conductive layer formed by doping the transparent conductive oxide layer with the conductive material, are respectively positioned between the emitter region and the first main electrode and between the first surface field region and the second main electrode. Hence, conductivity of the first and second auxiliary electrodes is greatly improved. Further, an amount of carriers moving from the emitter region to the first main electrode and an amount of carriers moving from the first surface field region to the second main electrode greatly increase. As a result, efficiency of the solar cell is improved.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a partial perspective view of a solar cell according to an example embodiment of the invention;

FIG. 2 is a cross-sectional view taken along line II-II of FIG. 1;

FIG. 3 illustrates a conductive layer according to an example embodiment of the invention; and

FIG. 4 is a graph showing an ion energy when a reactive plasma deposition method and a sputtering method are used.

### DETAILED DESCRIPTION OF THE EMBODIMENTS

Reference will now be made in detail to embodiments of the invention, examples of which are illustrated in the accompanying drawings. This invention may, however, be embodied in many different forms and should not be construed as limited to the embodiments set forth herein.

Wherever possible, the same reference numbers will be used throughout the drawings to refer to the same or like parts. It will be paid attention that detailed description of known arts will be omitted if it is determined that the known arts can obscure the embodiments of the invention.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present.

In contrast, when an element is referred to as being “directly on” another element, there are no intervening elements present.

Further, it will be understood that when an element such as a layer, film, region, or substrate is referred to as being “entirely” on other element, it may be on the entire surface of the other element and may not be on a portion of an edge of the other element.

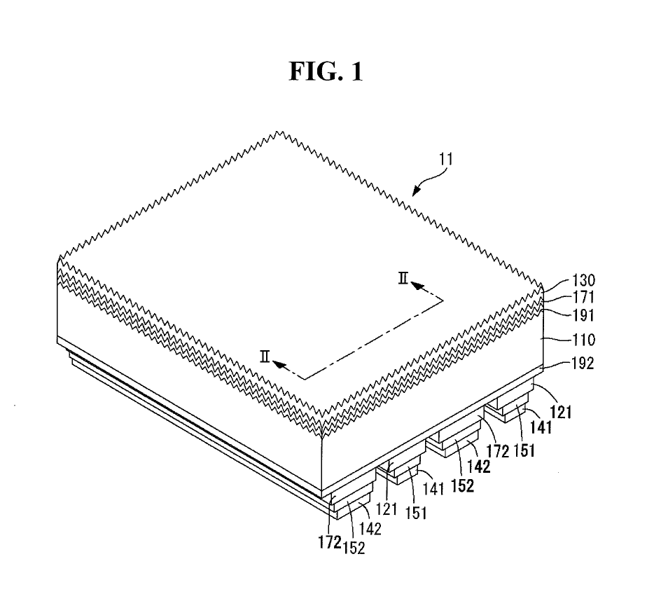

Example embodiments of the invention will be described with reference to FIGS. 1 to 4.

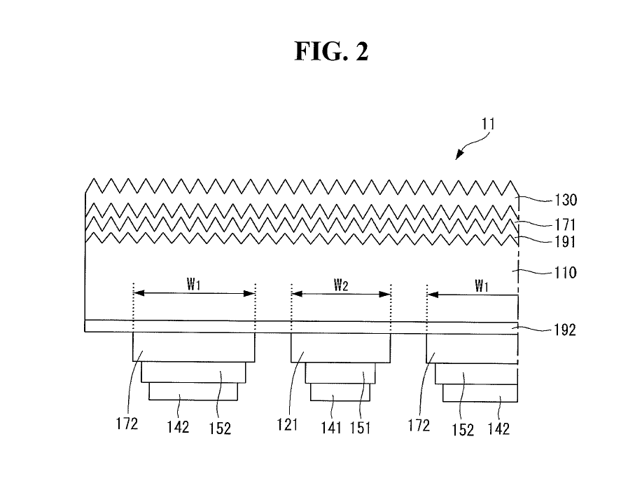

A solar cell according to an example embodiment of the invention is described in detail with reference to FIGS. 1 and 2.

As shown in FIGS. 1 and 2, a solar cell 11 according to an example embodiment of the invention includes a substrate 110, a front buffer (or a second buffer) 191 positioned on an incident surface (hereinafter, referred to as “a front surface” or “a second surface”) of the substrate 110 on which light is incident, a front surface field region (or a second surface field region) 171 positioned on the front buffer 191, an anti-reflection layer 130 positioned on the front surface field region 171, a back buffer (or a first buffer) 192 positioned on a surface (hereinafter, referred to as “a back surface” or “a first surface”) opposite the incident surface of the substrate 110, a plurality of emitter regions 121 positioned at the back buffer 192, a plurality of back surface field regions (or a plurality of first surface field regions) 172 which are positioned on the back buffer 192 and are separated from the plurality of emitter regions 121, a plurality of first auxiliary electrodes 151 respectively positioned on the plurality of emitter regions 121, a plurality of second auxiliary electrodes 152 respectively positioned on the plurality of back surface field regions 172, a plurality of first main electrodes 141 respectively positioned on the plurality of first auxiliary electrodes 151, and a plurality of second main electrodes 142 respectively positioned on the plurality of second auxiliary electrodes 152. The first auxiliary electrode 151 and the first main electrode 141 positioned on the first auxiliary electrode 151 form a first electrode part, and the second auxiliary electrode 152 and the second main electrode 142 positioned on the second auxiliary electrode 152 form a second electrode part.

In general, light is not incident on the back surface of the substrate 110. However, if necessary or desired, light may be incident on the back surface of the substrate 110. In this instance, an amount of light incident on the back surface of the substrate 110 is much less than an amount of light incident on the front surface of the substrate 110.

The substrate 110 is a semiconductor substrate formed of semiconductor such as first conductive type silicon, for example, n-type silicon, though not required. The semiconductor used in the substrate 110 is crystalline semiconductor such as single crystal silicon and polycrystalline silicon. The n-type substrate 110 is doped with impurities of a group V element such as phosphorus (P), arsenic (As), and antimony (Sb).

Alternatively, the substrate 110 may be of a p-type and/or may be formed of a semiconductor material other than silicon. If the substrate 110 is of the p-type, the substrate 110 may be doped with impurities of a group III element such as boron (B), gallium (Ga), and indium (In).

As shown in FIGS. 1 and 2, a separate texturing process is performed on the flat front surface of the substrate 110 to form a textured surface corresponding to an uneven surface having a plurality of protrusions and a plurality of depressions or having uneven characteristics. In this instance, the front buffer 191, the front surface field region 171, and the anti-reflection layer 130 positioned on the front surface of the substrate 110 each have the textured surface.

As described above, because the front surface of the substrate 110 is textured, an incident area of the substrate 110 increases and a light reflectance decreases due to a plurality of reflection operations resulting from the protrusions and the depressions. Hence, an amount of light incident on the substrate 110 increases, and the efficiency of the solar cell 11 is improved.

As shown in FIGS. 1 and 2, in the solar cell 11 according to the embodiment of the invention, the back surface of the substrate 110 has not a textured surface but a flat surface. Hence, components positioned on the back surface of the substrate 110 are uniformly and stably formed close to the back surface of the substrate 110, and thus a contact resistance between the substrate 110 and the components on the back surface of the substrate 110 is reduced. However, unlike the embodiment of the invention, the back surface of the substrate 110 may have the textured surface in other embodiments of the invention.

The front buffer 191 positioned on the front surface of the substrate 110 is formed of non-crystalline semiconductor. For example, the front buffer 191 may be formed of intrinsic hydrogenated amorphous silicon (i-a-Si:H).

The front buffer 191 may be positioned on the entire front surface of the substrate 110 or the entire front surface of the substrate 110 except an edge.

The front buffer 191 performs a passivation function which converts a defect, for example, dangling bonds existing at and around the surface of the substrate 110 into stable bonds using hydrogen (H) contained in the front buffer 191 to thereby prevent or reduce a recombination and/or a disappearance of carriers moving to the surface of the substrate 110. Thus, the front buffer 191 reduces an amount of carriers lost by the defect.

In the embodiment of the invention, many defects exist at and around the surface of the substrate 110 because of the p-type or n-type impurities contained in the substrate 110.

Accordingly, in the embodiment of the invention, because the front buffer 191 is formed directly on the surface of the substrate 110 having the many defects, an amount of carriers lost at and around the surface of the substrate 110 by the defects is reduced.

The front buffer 191 may have a thickness of about 1 nm to 10 nm.

When the thickness of the front buffer 191 is equal to or greater than about 1 nm, the front buffer 191 is uniformly applied to the front surface of the substrate 110 and thus may perform well the passivation function. Further, when the thickness of the front buffer 191 is equal to or less than about 10 nm, an amount of light absorbed in the front buffer 191 is reduced, and thus an amount of light incident on the substrate 110 may increase.

The front surface field region 171 positioned on the front buffer 191 is formed of non-crystalline semiconductor (for example, amorphous silicon) containing impurities of the same conductive type (for example, n-type) as the substrate 110. Further, a concentration of impurities of the first conductive type contained in the front buffer 191 is higher than an impurity concentration of the substrate 110. Thus, the front surface field region 171 and the substrate 110 form a heterojunction. When the front surface field region 171 is of the n-type, the front surface field region 171 may be doped with impurities of a group V element.

The front surface field region 171 forms a potential barrier by a difference between impurity concentrations of the substrate 110 and the front surface field region 171, thereby performing a front surface field function preventing holes from moving to the front surface of the substrate 110. Thus, a front surface field effect, in which holes moving to the front surface of the substrate 110 return to the back surface of the substrate 110 by the potential barrier, is obtained by the front surface field region 171. As a result, an output amount of holes output from the back surface of the substrate 110 to an external device increases, and an amount of carriers lost by a recombination and/or a disappearance of electrons and holes at and around the front surface of the substrate 110 is reduced.

A built-in potential difference increases because of a difference between energy band gaps resulting from the heterojunction between the front surface field region 171 and the substrate 110, i.e., a difference between energy band gaps of crystalline silicon and non-crystalline silicon. Hence, an open-circuit voltage of the solar cell 11 increases, and a fill factor of the solar cell 11 is improved.

In the embodiment of the invention, because the front surface field region 171, which forms the heterojunction along with the substrate 110, is positioned on the front buffer 191 formed of non-crystalline semiconductor, for example, intrinsic hydrogenated amorphous silicon, the fill factor of the solar cell 11 is improved more stably.

In other words, a crystallization phenomenon of the front surface field region 171 containing amorphous silicon formed on the front buffer 191 containing intrinsic hydrogenated amorphous silicon is much less than a crystallization phenomenon of the front surface field region 171 containing non-crystalline semiconductor formed directly on the substrate 110 containing crystalline semiconductor.

For example, when non-crystalline semiconductor is formed directly on the substrate 110 containing crystalline semiconductor, the crystallization of the front surface field region 171 formed of amorphous silicon is carried out under the influence of the crystallization of the substrate 110. In this instance, the effect obtained by the heterojunction between the front surface field region 171 and the substrate 110 is reduced or is not generated.

However, in the embodiment of the invention, because the front buffer 191 formed of intrinsic hydrogenated amorphous silicon not having crystallizability is positioned between the substrate 110 of crystalline semiconductor and the front surface field region 171 of non-crystalline semiconductor, the crystallization phenomenon of the front surface field region 171 is not generated. Hence, the front surface field region 171 stably maintains a non-crystalline semiconductor state and thus maintains a heterojunction state along with the substrate 110.

The front surface field region 171 performs a passivation function along with the front buffer 191 as well as the front surface field function. Namely, the front surface field region 171 performs the passivation function using hydrogen (H) contained in the front surface field region 171 in the same manner as the front buffer 191. Hence, because the front surface field region 171 stably supplements the passivation function of the front buffer 191 having the thin thickness, a passivation effect at the front surface of the substrate 110 is stably obtained.

The anti-reflection layer 130 positioned on the front surface field region 171 reduces a reflectance of light incident on the solar cell 11 and increases selectivity of a predetermined wavelength band, thereby increasing efficiency of the solar cell 11. The anti-reflection layer 130 may be formed of a material capable of reducing or decreasing the reflection of light, for example, hydrogenated silicon nitride (SiNx:H), hydrogenated amorphous silicon nitride (a-SiNx:H), and hydrogenated silicon oxide (SiOx:H). The anti-reflection layer 130 may have a thickness of about 70 nm to 90 nm. The anti-reflection layer 130 may be transparent.

When the thickness of the anti-reflection layer 130 is within the above range, the anti-reflection layer 130 may have a good transmittance of light and may increase an amount of light incident on the substrate 110.

In the embodiment of the invention, the anti-reflection layer 130 has a single-layered structure, but may have a multi-layered structure, for example, a double-layered structure. The anti-reflection layer 130 may be omitted, if necessary or desired. Further, the anti-reflection layer 130 performs a passivation function similar to the passivation function of the front surface field region 171 and the front buffer 191.

Because silicon nitride or silicon oxide has characteristics of positive fixed charges, the anti-reflection layer 130 formed of silicon nitride or silicon oxide has characteristics of positive fixed charges.

Because holes serving as minority carriers in the n-type substrate 110 have the same positive polarity as the anti-reflection layer 130, the holes are pushed to the back surface of the substrate 110, at which the emitter regions 121 are formed, on the opposite side of the anti-reflection layer 130 due to the polarity of the anti-reflection layer 130.

Accordingly, an amount of holes moving to the front surface of the substrate 110 decreases by the anti-reflection layer 130, and an amount of carriers lost by a recombination and/or a disappearance of electrons and holes at and around the front surface of the substrate 110 is reduced. Further, an amount of holes moving to the back surface of the substrate 110, at which the emitter regions 121 are formed, increases.

As a result, the efficiency of the solar cell 11 is improved by because of the passivation function of the front buffer 191 and the anti-reflection layer 130 positioned on the front surface of the substrate 110 and characteristics of fixed charges of the anti-reflection layer 130.

In an alternative example, at least one of the front buffer 191, the front surface field region 171, and the anti-reflection layer 130 may be omitted if necessary or desired.

The back buffer 192 is positioned on the back surface of the substrate 110, at which the emitter regions 121 and the back surface field regions 172 are formed, and on the back surface of the substrate 110 between the emitter regions 121 and the back surface field regions 172 which are positioned adjacent to each other. The back buffer 192 may be formed of intrinsic amorphous silicon.

The back buffer 192 may be hydrogenated using a gas injected for the formation of the back buffer 192. In this instance, the back buffer 192 contains hydrogen (H). Thus, in this instance, the back buffer 192 may be formed of hydrogenated intrinsic amorphous material.

The back buffer 192 performs a passivation function in the same manner as the front buffer 191, thereby preventing or reducing a recombination and/or a disappearance of carriers moving to the back surface of the substrate 110.

The back buffer 192 has a thickness to the extent that carriers moving to the back surface of the substrate 110 may pass through the back buffer 192 and may move to the back surface field regions 172 and the emitter regions 121. For example, the thickness of the back buffer 192 may be about 1 nm to 10 nm.

When the thickness of the back buffer 192 is equal to or greater than about 1 nm, the back buffer 192 is uniformly applied to the back surface of the substrate 110 and thus may perform well the passivation function. Further, when the thickness of the back buffer 192 is equal to or less than about 10 nm, the back buffer 192 makes it easier for carriers to move. Further, an amount of light, which passes through the substrate 110 and is absorbed in the back buffer 192, further decreases, and thus an amount of light reincident on the substrate 110 may increase.

The back buffer 192 may be omitted, if necessary or desired.

Unlike the embodiment of the invention, the back buffer 192 may be positioned between the back surface of the substrate 110 and the emitter regions 121 and between the back surface of the substrate 110 and the back surface field regions 172. Namely, the back buffer 192 may be positioned only between the emitter regions 121 and the back surface field regions 172 which are positioned adjacent to each other.

The plurality of emitter regions 121 are positioned on the back buffer 192 to be separated from one another and extend parallel to one another in a fixed direction.

Each of the emitter regions 121 is an impurity region doped with impurities of a second conductive type (for example, p-type) opposite the first conductive type (for example, n-type) of the substrate 110. Each emitter region 121 is formed of a semiconductor different from the substrate 110, for example, non-crystalline semiconductor such as amorphous silicon. Thus, the plurality of emitter regions 121 form a heterojunction as well as a p-n junction along with the substrate 110.

When the emitter regions 121 are of the p-type, the emitter regions 121 may contain impurities of a group III element such as B, Ga, and In. On the contrary, if the emitter regions 121 are of the n-type, the emitter regions 121 may contain impurities of a group V element such as P, As, and Sb.

Because each emitter region 121 forms the p-n junction along with the substrate 110, the emitter regions 121 may be of the n-type if the substrate 110 is of the p-type unlike the embodiment described above. In this instance, electrons move to the emitter regions 121, and holes move to the back surface field regions 172.

The plurality of back surface field regions 172 are positioned directly on the back buffer 192 to be separated from one another and extend parallel to one another in a fixed direction. The back surface field regions 172 are separated from the emitter regions 121. Thus, as shown in FIGS. 1 and 2, the back surface field regions 172 and the emitter regions 121 are alternately positioned on the back buffer 192.

The back surface field regions 172 are formed of non-crystalline semiconductor such as amorphous silicon in the same manner as the front surface field region 171. Each of the back surface field regions 172 is a region (for example, an n⁺-type region) which is more heavily doped than the substrate 110 with impurities of the same conductive type as the substrate 110. Thus, the back surface field regions 172 form a heterojunction along with the substrate 110 in the same manner as the emitter regions 121.

Accordingly, carriers, for example, electron-hole pairs produced by light incident on the substrate 110 are separated into electrons and holes by a built-in potential difference resulting from the p-n junction between the substrate 110 and the emitter regions 121. The separated electrons move to the n-type semiconductor, and the separated holes move to the p-type semiconductor. As in the embodiment of the invention, when the substrate 110 is of the n-type and the emitter regions 121 are of the p-type, the holes move to the emitter regions 121, and the electrons move to the back surface field regions 172 having an impurity concentration higher than the substrate 110.

The back surface field regions 172 form a potential barrier by a difference between impurity concentrations of the substrate 110 and the back surface field regions 172 in the same manner as the front surface field region 171, thereby preventing holes from moving to the second main electrodes 142 and making it easier for electrons to move to the second main electrodes 142. Hence, an amount of carriers lost by a recombination and/or a disappearance of electrons and holes at and around the second main electrodes 142 is reduced, and an amount of electrons moving from the substrate 110 to the second main electrodes 142 increases.

As described above, the open-circuit voltage of the solar cell 11 increases, and the fill factor of the solar cell 11 is improved by a difference between energy band gaps resulting from the heterojunction between the substrate 110 and the back surface field regions 172 and the heterojunction between the substrate 110 and the emitter regions 121.

A width W1 of each of the back surface field regions 172 contacting the back surface of the substrate 110 is different from a width W2 of each of the emitter regions 121 contacting the back surface of the substrate 110. Namely, the width W1 of the back surface field region 172 is greater than the width W2 of the emitter region 121. Hence, an area of the back surface of the substrate 110 covered by the back surface field regions 172 increases, and the passivation effect and the back surface field effect obtained by the back surface field regions 172 are improved.

On the other hand, the width W1 of the back surface field region 172 may be less than the width W2 of the emitter region 121. In this instance, a formation area of the p-n junction increases, and thus mobility of electrons and holes increases. Hence, it is advantageous to collect the holes having the mobility less than the electrons.

Because the back buffer 192 containing an insulating material is positioned between the back surface field region 172 and the emitter region 121, a short circuit between the back surface field region 172 and the emitter region 121 is prevented, and thus a leakage of carriers is prevented. Further, a loss of carriers by an electrical interference between the back surface field region 172 and the emitter region 121 is prevented. As a result, an amount of a leakage current of the solar cell 11 is reduced.

The plurality of first auxiliary electrodes 151 are respectively positioned on the plurality of emitter regions 121 and extend along the emitter regions 121. The plurality of second auxiliary electrodes 152 are respectively positioned on the plurality of back surface field regions 172 and extend along the back surface field regions 172.

The plurality of first auxiliary electrodes 151 are formed of the same material and have the same structure. The plurality of second auxiliary electrodes 152 are formed of the same material and have the same structure. Further, each first auxiliary electrode 151 and each second auxiliary electrode 152 are formed of the same material and have the same structure.

Each of the first and second auxiliary electrodes 151 and 152 is a transparent conductive layer obtained by doping a transparent conductive oxide layer containing transparent conductive oxide (TCO) with a conductive material such as aluminum (Al). For example, the transparent conductive layer may be an Al-doped ZnO layer. Hence, the first auxiliary electrodes 151 are electrically connected to the emitter regions 121, and the second auxiliary electrodes 152 are electrically connected to the back surface field regions 172.

Each of the first and second auxiliary electrodes 151 and 152 is formed using an atomic layer deposition (ALD) method and includes an aluminum oxide (Al₂O₃) layer and a zinc oxide (ZnO) layer thicker than the aluminum oxide (Al₂O₃) layer. Thus, the aluminum oxide (Al₂O₃) layer and the zinc oxide (ZnO) layer may be formed using the atomic layer deposition method.

An atomic layer deposition cycle to form the aluminum oxide (Al₂O₃) layer or the zinc oxide (ZnO) layer may include a metal (Al or Zn) precursor injection stage, a chamber purging stage, an oxidizer injection stage, and a chamber purging stage.

In the embodiment of the invention, the aluminum oxide (Al₂O₃) layer may be formed through one atomic layer deposition cycle, and the zinc oxide (ZnO) layer may be formed through the plurality of atomic layer deposition cycles.

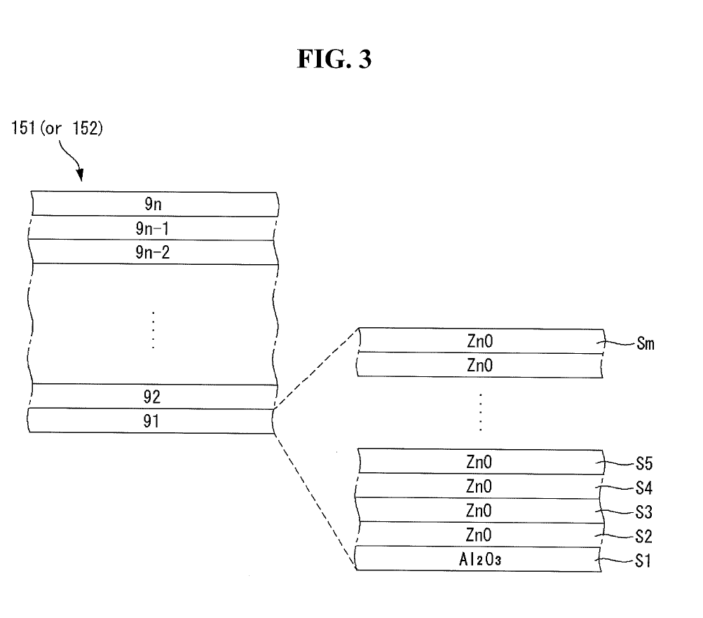

As shown in FIG. 3, each of the first and second auxiliary electrodes 151 and 152 has a nanolaminate structure including a plurality of layers 91 to 9n. Each of the layers 91 to 9n includes a plurality of sub-layers S1 to Sm, each of which is formed each time the atomic layer deposition cycle is performed once.

As described above, because one atomic layer deposition cycle is performed to form the aluminum oxide (Al₂O₃) layer, one aluminum oxide (Al₂O₃) layer is formed. Further, because the plurality of atomic layer deposition cycles are performed to form the zinc oxide (ZnO) layer, the plurality of zinc oxide (ZnO) layers are formed.

In this instance, 10 to 40 atomic layer deposition cycles may be performed to form the zinc oxide (ZnO) layer. A thickness of the aluminum oxide (Al₂O₃) layer formed through one atomic layer deposition cycle may be about 1 Å to 1.5 Å. A thickness of the zinc oxide (ZnO) layer formed through one atomic layer deposition cycle may be about 1.3 Å to 2.4 Å.

Accordingly, in the total thickness of each of the first and second auxiliary electrodes 151 and 152, a thickness ratio of the aluminum oxide (Al₂O₃) layer to the zinc oxide (ZnO) layer may be about 1:8 to 1:80. For example, the thickness of the aluminum oxide (Al₂O₃) layer may be about 1 Å to 1.5 Å, and the thickness of the zinc oxide (ZnO) layer formed through the plurality of atomic layer deposition cycles may be about 10 Å to 80 Å.

In FIG. 3, a lowermost sub-layer S1 (positioned closest to the emitter region 121 or the back surface field region 172) of each of the layers 91 to 9n is formed of the aluminum oxide (Al₂O₃) layer, and other sub-layers S2 to Sm positioned on the lowermost sub-layer S1 are formed of the zinc oxide (ZnO) layer.

However, the embodiment of the invention is not limited thereto. For example, the aluminum oxide (Al₂O₃) layer may correspond to an uppermost sub-layer Sm (positioned farthest from the emitter region 121 or the back surface field region 172 and positioned adjacent to the first or second main electrode 141 or 142) of each of the layers 91 to 9n, or may correspond to one of the sub-layers S2 to Sm−1 existing between the lowermost sub-layer S1 and the uppermost sub-layer Sm.

As shown in FIG. 3, the total thickness of each of the first and second auxiliary electrodes 151 and 152 including the plurality of layers 91 to 9n each including the aluminum oxide (Al₂O₃) layer S1 and the zinc oxide (ZnO) layers S2 to Sm thicker than the aluminum oxide (Al₂O₃) layer 51 may be about 100 nm to 1,000 nm.

As described above, because each of the first and second auxiliary electrodes 151 and 152 is formed using Al-doped ZnO obtained by adding aluminum oxide (Al₂O₃) to zinc oxide (ZnO) corresponding to transparent conductive oxide (TCO), conductivity of each of the first and second auxiliary electrodes 151 and 152 is much greater than conductivity of those formed of zinc oxide (ZnO), on which aluminum (Al) is not doped.

For example, zinc oxide (ZnO) has conductivity of about 250 S/cm, and the conductivity of each of the first and second auxiliary electrodes 151 and 152 formed of Al-doped ZnO may be about 1,000 S/cm to 3,000 S/cm.

Further, a sheet resistance of each of the first and second auxiliary electrodes 151 and 152 formed of Al-doped ZnO may be about 6Ω/sq. to 80Ω/sq. and is less than a sheet resistance (about 200Ω/sq. to 300Ω/sq.) of the substrate 110.

The embodiment of the invention used aluminum (Al) so as to increase the conductivity of the first and second auxiliary electrodes 151 and 152, but is not limited thereto. Other conductive materials may be used. For example, silicon (Si), hydrogen fluoride (HF), manganese (Mn), and copper (Cu) may be used instead of aluminum (Al).

In the embodiment of the invention, because the conductivity of the first and second auxiliary electrodes 151 and 152 increases due to the doping of aluminum (Al), holes and electrons respectively moving to the emitter region 121 and the back surface field region 172 may move more easily from the substrate 110 to the first and second auxiliary electrodes 151 and 152, respectively. Thus, an amount of holes and electrons moving to the first and second auxiliary electrodes 151 and 152 increases.

In the embodiment of the invention, each of the first and second auxiliary electrodes 151 and 152 is formed using the atomic layer deposition method, in which a physical stack manner is performed and also a chemical combination between lower layers, i.e., the emitter region 121 and the back surface field region 172 is performed, instead of a sputtering method or an e-beam evaporation method performed using only a physical stack manner. Therefore, a contact strength between the emitter region 121 and the back surface field region 172 is improved. Hence, an amount of carriers moving from the emitter region 121 and the back surface field region 172 to the first and second auxiliary electrodes 151 and 152 further increases.

In the embodiment of the invention, when the total thickness of each of the first and second auxiliary electrodes 151 and 152 is equal to or greater than about 100 nm or the number of zinc oxide (ZnO) layers is equal to or greater than 10, the first and second auxiliary electrodes 151 and 152 are uniformly formed on the back surface of the substrate 110, and the conductivity of the first and second auxiliary electrodes 151 and 152 is stably secured. Further, when the total thickness of each of the first and second auxiliary electrodes 151 and 152 is equal to or less than about 1,000 nm or the number of zinc oxide (ZnO) layers is equal to or less than 30, an increase in time required to manufacture the first and second auxiliary electrodes 151 and 152 is prevented.

The first and second auxiliary electrodes 151 and 152 respectively protect the emitter region 121 and the back surface field region 172 from atmospheric oxygen. Thus, changes in characteristics of the emitter region 121 and the back surface field region 172 resulting from an oxidation phenomenon are prevented. The emitter region 121 and the back surface field region 172 again reflects light passing through the substrate 110 to the substrate 110, thereby serving as a reflector increasing an amount of light incident on the substrate 110.

Each of the first and second auxiliary electrodes 151 and 152 performs the passivation function.

In other words, the layers constituting each of the first and second auxiliary electrodes 151 and 152 are stacked using the atomic layer deposition method, a defect resulting from dangling bonds existing at and around the back surface of the substrate 110 is combined with aluminum (Al) or oxygen (O) and thus is changed to stable bonds. Therefore, a loss of carriers by the defect is prevented.

Accordingly, the defects existing at the surfaces of the emitter region 121 and the back surface field region 172 respectively contacting the first and second auxiliary electrodes 151 and 152 are solved by the first and second auxiliary electrodes 151 and 152. Hence, an amount of carriers moving from the emitter region 121 and the back surface field region 172 to the first and second auxiliary electrodes 151 and 152 further increases.

The plurality of first main electrodes 141 respectively positioned on the plurality of first auxiliary electrodes 151 elongate along the first auxiliary electrodes 151 and are electrically and physically connected to the first auxiliary electrodes 151. In FIGS. 1 and 2, each first main electrode 141 has the same plane shape as the first auxiliary electrode 151 underlying the first main electrode 141, but may have other plane shapes.

Each first main electrode 141 collects carriers (for example, holes), which move to the corresponding emitter region 121 and are transmitted through the first auxiliary electrode 151. In this instance, as described above, because the thickness of the first auxiliary electrode 151 varies depending on its position, a collection efficiency of carriers from the emitter region 121 to the first auxiliary electrode 151 is improved. As a result, an amount of carriers output from the first main electrode 141 increases.

The plurality of second main electrodes 142 respectively positioned on the plurality of second auxiliary electrodes 152 elongate along the second auxiliary electrodes 152 and are electrically and physically connected to the second auxiliary electrodes 152. In FIGS. 1 and 2, each second main electrode 142 has the same plane shape as the second auxiliary electrode 152 underlying the second main electrode 142, but may have other plane shapes.

Each second main electrode 142 collects carriers (for example, electrons), which move to the corresponding back surface field region 172 and are transmitted through the second auxiliary electrodes 152.

In the embodiment of the invention, the first and second main electrodes 141 and 142 are formed of silver (Ag) or Al—Ag alloy.

In the embodiment of the invention, the conductivity of the first and second auxiliary electrodes 151 and 152 increases by doping aluminum (Al) on the first and second auxiliary electrodes 151 and 152 formed of transparent conductive oxide. Therefore, even if the first and second main electrodes 141 and 142 are formed of copper (Cu), aluminum (Al), etc., which have conductivity less than silver (Ag) but are much cheaper than silver (Ag), an amount of carriers moving from the first and second auxiliary electrodes 151 and 152 to the first and second main electrodes 141 and 142 may not decrease.

As a result, the manufacturing cost of the solar cell 11 is greatly reduced without a reduction in the efficiency of the solar cell 11.

Because the first and second auxiliary electrodes 151 and 152 formed of the transparent conductive material are respectively positioned between the emitter region 121 and the back surface field region 172, which are formed of the semiconductor material such as silicon, and the first and second main electrodes 141 and 142 formed of the metal material, an ohmic contact is formed between the emitter region 121 and the back surface field region 172 and the first and second main electrodes 141 and 142. Hence, an adhesive strength (i.e., contact characteristic) between the semiconductor material and the metal material, which generally have a weak adhesive strength therebetween, is improved by the transparent conductive material therebetween.

The solar cell 11 shown in FIGS. 1 and 2 has the heterojunction structure and is a back contact solar cell, in which the first and second auxiliary electrodes 151 and 152 respectively connected to the emitter regions 121 and the back surface field regions 172 and the first and second main electrodes 141 and 142 are positioned on the back surface of the substrate 110. An operation of the solar cell 11 having the above-described structure is described below.

When light irradiated onto the solar cell 11 sequentially passes through the anti-reflection layer 130, the front surface field region 171, and the front buffer 191 and is incident on the substrate 110, electrons and holes are generated in the substrate 110 by light energy produced based on the incident light. In this instance, because the front surface of the substrate 110 is the textured surface, a light reflectance at the front surface of the substrate 110 is reduced. Further, because both incident and reflective operations are performed at the textured surface of the substrate 110 to increase a light absorptance of the substrate 110, the efficiency of the solar cell 11 is improved. In addition, because a reflection loss of light incident on the substrate 110 is reduced by the anti-reflection layer 130, an amount of light incident on the substrate 110 further increases.

The holes move to the p-type emitter regions 121 and the electrons move to the n-type back surface field regions 172 by the p-n junction of the substrate 110 and the emitter regions 121. The holes moving to the emitter regions 121 are transmitted to the first main electrodes 141 through the first auxiliary electrodes 151 and then are collected by the first main electrodes 141. The electrons moving to the back surface field regions 172 are transmitted to the second main electrodes 142 through the second auxiliary electrodes 152 and then are collected by the second main electrodes 142. When the first and second main electrodes 141 and 142 are connected to each other using electric wires, current flows therein to thereby enable use of the current for electric power.

In the embodiment of the invention, because the first and second auxiliary electrodes 151 and 152 are formed of Al-doped transparent conductive oxide, the conductivity of the first and second auxiliary electrodes 151 and 152 is improved. Hence, an amount of carriers moving from the emitter regions 121 and the back surface field regions 172 to the first and second auxiliary electrodes 151 and 152 increases.

Further, the first and second auxiliary electrodes 151 and 152 are formed using the atomic layer deposition method, and thus are chemically combined with the emitter region 121 and the back surface field region 172 underlying the first and second auxiliary electrodes 151 and 152. Hence, a contact strength between the emitter region 121 and the first auxiliary electrode 151 and a contact strength between the back surface field region 172 and the second auxiliary electrode 152 increase, and an amount of carriers moving from the emitter region 121 and the back surface field region 172 to the first and second auxiliary electrodes 151 and 152 further increases.

In addition, because the first and second auxiliary electrodes 151 and 152 formed of the transparent conductive material are positioned between the emitter region 121 and the back surface field region 172, which are formed of the semiconductor material, and the first and second main electrodes 141 and 142 formed of the metal material, the ohmic contact is formed between the emitter region 121 and the back surface field region 172 and the first and second main electrodes 141 and 142. Hence, an amount of carriers moving from the emitter region 121 and the back surface field region 172 to the first and second main electrodes 141 and 142 further increases.

In the embodiment of the invention, because the first and second auxiliary electrodes 151 and 152, which are the transparent conductive layer formed by doping the transparent conductive oxide layer with the conductive material, are formed using the atomic layer deposition method, a damaged portion is prevented from being generated in each of the emitter region 121 and the back surface field region 172 underlying the first and second auxiliary electrodes 151 and 152. Hence, an amount of carriers moving from the emitter region 121 and the back surface field region 172 to the first and second auxiliary electrodes 151 and 152 further increases.

In other words, transparent conductive oxide such as indium tin oxide (ITO) and zinc oxide (ZnO) is generally formed using a sputtering method or a reactive plasma deposition (RPD) method. These deposition methods are physically deposition methods, in which a material for layer deposition is accelerated into the surface of a lower layer (for example, the emitter region and the back surface field region) to deposit a desired layer. Therefore, the layer deposition material collides with the surface of the lower layer. As a result, many damaged portions are generated in the surface of the lower layer.

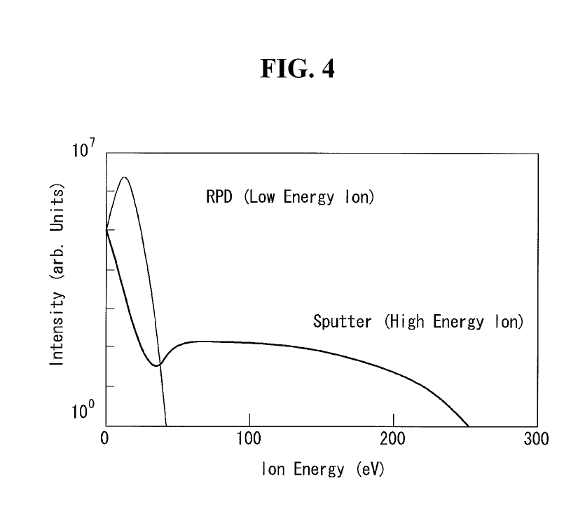

For example, as shown in FIG. 4, when the reactive plasma deposition method was used, maximum ion energy concerned in the layer deposition was about 50 eV. Further, when the sputtering method was used, maximum ion energy concerned in the layer deposition was about 250 eV. Thus, if ions having the above ion energy collide with the surface of the emitter region or the surface of the back surface field region, many damaged portions will be generated in the surface of the emitter region or the surface of the back surface field region.

When indium tin oxide (ITO) is formed using the reactive plasma deposition method and the sputtering method generating the damaged portions in the surface of the emitter region or the surface of the back surface field region, a life time of carriers is greatly reduced because of the damaged portions of the emitter region and the back surface field region.

For example, when the life time of carriers before the deposition of ITO was about 1,400 μs, the life time of carriers was reduced to about 1,320 μs when an ITO layer was formed using the reactive plasma deposition method, and the life time of carriers was reduced to about 1,000 μs when the ITO layer was formed using the sputtering method.

As above described, when the transparent conductive oxide layer, for example, the ITO layer is formed between the emitter region 121 and the back surface field region 172 and the first and second main electrodes 141 and 142 using the sputtering method or the reactive plasma deposition method, a damage of the solar cell 11 is caused because of the damaged portions generated in the surface of the emitter region 121 and the surface of the back surface field region 172.

However, in the embodiment of the invention, because the transparent conductive layer is formed using the atomic layer deposition method not generating the physical damage in the surface of the emitter region 121 and the surface of the back surface field region 172, the efficiency of the solar cell 11 is further improved. Further, because the atomic layer deposition method is performed at a low temperature of about 80° C. to 200° C., a degradation phenomenon of the substrate 110 and the components (for example, the emitter regions 121 and the back surface field regions 172) on the substrate 110 resulting from heat is reduced.

In an alternative embodiment, the embodiment of the invention may be applied to an interdigitated back contact solar cell, in which both an emitter region and a back surface field region are positioned at a back surface of a substrate, a first auxiliary electrode and a first electrode connected to the emitter region and a second auxiliary electrode and a second electrode connected to the back surface field region are positioned on the back surface of the substrate, and the substrate, the emitter region, and the back surface field region form a homojunction. In other words, in the interdigitated back contact solar cell, the first auxiliary electrode, which is positioned between the emitter region and the first electrode and is formed of transparent conductive oxide such as indium tin oxide (ITO), and the second auxiliary electrode, which is positioned between the back surface field region and the second electrode and is formed of transparent conductive oxide such as indium tin oxide (ITO), may be formed as the first and second auxiliary electrodes 151 and 152 according to the embodiment of the invention.

Further, in addition to the interdigitated back contact solar cell, when auxiliary electrodes formed of transparent conductive oxide are positioned between an emitter region and a back surface field region, each of which is formed of a semiconductor, and electrodes formed of metal, the auxiliary electrodes may be replaced with the first and second auxiliary electrodes 151 and 152 according to the embodiment of the invention. Hence, the auxiliary electrodes may be a transparent conductive layer formed by doping a transparent conductive oxide layer with a conductive material such as aluminum (Al).

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell comprising:
a substrate of a first conductive type formed of a crystalline semiconductor;
an emitter region positioned at a first surface of the substrate, the emitter region having a second conductive type different from the first conductive type;
a first surface field region which is positioned at the first surface of the substrate and separated from the emitter region and has the first conductive type;
a first auxiliary electrode positioned directly on the emitter region;
a second auxiliary electrode positioned directly on the first surface field region;
a first main electrode positioned directly on the first auxiliary electrode; and
a second main electrode positioned directly on the second auxiliary electrode,
wherein each of the first and second auxiliary electrodes is a transparent conductive layer formed by doping a transparent conductive oxide layer having conductivity of 1,000 S/cm to 3,000 S/cm with a conductive material.

2. The solar cell of claim 1, wherein each of the first and second auxiliary electrodes includes a plurality of layers each including a first oxide layer and a second oxide layer thicker than the first oxide layer.

3. The solar cell of claim 2, wherein the first oxide layer is an aluminum oxide layer, and the second oxide layer is a zinc oxide layer.

4. The solar cell of claim 3, wherein a thickness ratio of the first oxide layer to the second oxide layer is about 1:8 to 1:80.

5. The solar cell of claim 4, wherein each of the first and second auxiliary electrodes has a thickness of 100 nm to 1,000 nm.

6. The solar cell of claim 1, further comprising a first buffer which is positioned between the first surface of the substrate and the emitter region and between the first surface of the substrate and the first surface field region and is formed of a non-crystalline semiconductor.

7. The solar cell of claim 1, further comprising a second buffer which is positioned on a second surface opposite the first surface of the substrate and is formed of a non-crystalline semiconductor.

8. The solar cell of claim 1, further comprising a second surface field region which is positioned at a second surface opposite the first surface of the substrate and has the first conductive type.

9. The solar cell of claim 1, further comprising an anti-reflection layer which is positioned on a second surface opposite the first surface of the substrate and decreases reflection of light.

10. The solar cell of claim 1, wherein the substrate is a crystalline semiconductor, and the emitter region and the first surface field region are a non-crystalline semiconductor.

11. The solar cell of claim 1, wherein the substrate is a crystalline semiconductor, and the emitter region and the first surface field region are a crystalline semiconductor.

12. The solar cell of claim 1, wherein light is not incident on the first surface of the substrate.

13. The solar cell of claim 1, wherein each of the first and second auxiliary electrodes has a nanolaminate structure including a plurality of layers, whereby each of the plurality of layers includes a plurality of sub-layers, each of which is formed each time an atomic layer deposition cycle is performed once.

14. The solar cell of claim 13, wherein one of the plurality of sub-layers is an aluminum oxide layer, and the remainder of the plurality of sub-layers are zinc oxide layers.

15. The solar cell of claim 14, wherein the number of the zinc oxide layers are 10 to 40.

16. The solar cell of claim 14, wherein a thickness of the aluminum oxide layer is about 1 Å to 1.5 Å, and a thickness of each zinc oxide layer is about 1.3 Å to 2.4 Å.

17. The solar cell of claim 14, wherein the aluminum oxide layer is positioned directly on the emitter region or the first surface field region, and the zinc oxide layers are positioned on the aluminum oxide layer.
